(19) United States
(12) Patent Application Publication
(10) Pub. No.: US 2026/0214790 A1
(43) Pub. Date: Jul. 23, 2026

(54) CIRCUIT BOARD STRUCTURE AND MANUFACTURING METHOD THEREOF

(71) Applicant: UNIMICRON TECHNOLOGY CORP., Taoyuan City (TW)

(72) Inventors: Kai-Wei WANG, Taoyuan City (TW); Yan-Ting LAI, Taoyuan City (TW); Wei-Yu LIAO, Taoyuan City (TW); Chun-Jui HUANG, Taoyuan City (TW); Ching-Sheng CHEN, Taoyuan City (TW)

(73) Assignee: UNIMICRON TECHNOLOGY CORP., Taoyuan City (TW)

(21) Appl. No.: 19/446,208

(22) Filed: Jan. 12, 2026

Related U.S. Application Data
(60) Provisional application No. 63/746,475, filed on Jan. 17, 2025.

(51) Int. Cl. H05K 1/02

(52) U.S. Cl. CPC H05K 1/0296

(57) ABSTRACT

A circuit board structure and a manufacturing method thereof are provided. The circuit board structure includes a substrate, a first circuit pattern, a second circuit pattern, a first cover layer, and a dielectric layer. The first circuit pattern is disposed on the substrate and has a first circuit density. The second circuit pattern is disposed on the substrate and has a second circuit density, wherein the second circuit density is greater than the first circuit density. The first cover layer is disposed on the substrate and covers the first circuit pattern. The dielectric layer includes a first portion and a second portion. The first portion covers and is in contact with the upper surface of the first cover layer, and the second portion covers the second circuit pattern.

### CROSS REFERENCE TO RELATED APPLICATIONS

This application claims the benefit of U.S. provisional application No. 63/746,475, filed January 17, 2025, the entirety of which is incorporated by reference herein.

### BACKGROUND OF THE INVENTION

### Field of the Invention

The present disclosure relates to circuit board structures, and, in particular, it relates to a circuit board structure with excellent uniformity of dielectric thickness, and a manufacturing method thereof.

### Description of the Related Art

As electronic devices are used more widely, user expectations as to their high performance requirements are also increasing. To meet these demands, the design of circuit board structures in electronic devices increasingly employs more complex circuit patterns than previous generations. However, these complex circuit patterns can result in uneven dielectric layer thickness, leading to the structural stability of the circuit board structure being insufficient. In other words, while existing circuit board structures and manufacturing methods thereof have generally met their intended purposes, they do not meet requirements in all respects. Therefore, there is still a need for improvements to circuit board structures and the manufacturing methods thereof.

### BRIEF SUMMARY OF THE INVENTION

According to some embodiments, a circuit board structure is provided. The circuit board structure includes a substrate, a first circuit pattern, a second circuit pattern, a first cover layer, and a dielectric layer. The first circuit pattern is disposed on the substrate and has a first circuit density. The second circuit pattern is disposed on the substrate and has a second circuit density, wherein the second circuit density is greater than the first circuit density. The first cover layer is disposed on the substrate and covers the first circuit pattern. The dielectric layer includes a first portion and a second portion. The first portion covers and is in contact with the upper surface of the first cover layer, and the second portion covers the second circuit pattern.

In some embodiments, the first portion, the first cover layer, and the first circuit pattern together have a first thickness t1, and the second portion and the second circuit pattern together have a second thickness t2, wherein │(t1-t2)│≤30µm.

In some embodiments, the first portion, the first cover layer, and the first circuit pattern together have the first thickness t1, and the second portion and the second circuit pattern together have the second thickness t2, wherein │(t1-t2)│/(t1+t2)≤40%.

In some embodiments, the dielectric layer further includes a third portion covering and in contact with the upper surface of the substrate.

In some embodiments, the first portion, the first cover layer, and the first circuit pattern together have the first thickness t1, the third portion has a third thickness t3, and │(t1-t3)│≤30µm.

In some embodiments, the first portion, the first cover layer, and the first circuit pattern together have the first thickness t1, the third portion has the third thickness t3, and │(t1-t3)│/(t1+t3)≤40%.

In some embodiments, the circuit board structure further includes a second cover layer disposed on the substrate and partially covering the second circuit pattern, wherein the second portion covers and is in contact with the upper surface of the second cover layer.

In some embodiments, the upper surface of the first cover layer and the upper surface of the second cover layer are coplanar.

In some embodiments, the first portion, the first cover layer, and the first circuit pattern together have the first thickness t1, and the second portion, the second cover layer, and the second circuit pattern together have a second thickness t2, wherein │(t1-t2)│≤30µm.

In some embodiments, the first portion, the first cover layer, and the first circuit pattern together have the first thickness t1, and the second portion, the second cover layer, and the second circuit pattern together have a second thickness t2, wherein │(t1-t2)│/(t1+t2)≤40%.

In some embodiments, the material of the first cover layer is different from the material of the dielectric layer.

According to some embodiments, a manufacturing method of a circuit board structure is provided. The manufacturing method of the circuit board structure includes: forming a first circuit pattern on a substrate, wherein the first circuit pattern has a first circuit density; forming a second circuit pattern on the substrate, wherein the second circuit pattern has a second circuit density, and the second circuit density is greater than the first circuit density; forming a first cover layer on the first circuit pattern, wherein the first cover layer covers the first circuit pattern; and forming a dielectric layer on the first cover layer and the second circuit pattern.

In some embodiments, the dielectric layer includes a first portion and a second portion. The first portion covers and is in contact with the upper surface of the first cover layer, wherein the first portion, the first cover layer, and the first circuit pattern together have the first thickness t1. The second portion covers and is in contact with the upper surface of the second circuit pattern, wherein the second portion and the second circuit pattern together have a second thickness t2, wherein │(t1-t2)│≤30µm.

In some embodiments, the dielectric layer further includes a third portion covering and in contact with the upper surface of the substrate, wherein the third portion has the third thickness t3, wherein │(t1-t3)│≤30µm.

In some embodiments, the dielectric layer includes a first portion and a second portion. The first portion covers and is in contact with the upper surface of the first cover layer, wherein the first portion, the first cover layer, and the first circuit pattern together have the first thickness t1. The second portion covers and is in contact with the upper surface of the second circuit pattern, wherein the second portion and the second circuit pattern together have a second thickness t2, wherein │(t1-t2)│/(t1+t2)≤40%.

In some embodiments, the dielectric layer further includes a third portion covering and in contact with the upper surface of the substrate, wherein the third portion has the third thickness t3, wherein │(t1-t3)│/(t1+t3)≤40%.

In some embodiments, the first circuit density is less than or equal to 80%.

In some embodiments, the manufacturing method of the circuit board structure further includes: forming a second cover layer on the second circuit pattern, wherein the second cover layer partially covers the second circuit pattern and exposes a portion of the second circuit pattern; and forming the dielectric layer on the first cover layer, the second cover layer, and the second circuit pattern.

In some embodiments, the second circuit density is greater than 80%.

In some embodiments, the material of the first cover layer is different from the material of the dielectric layer.

The circuit board structure and the method thereof of the present disclosure may be employed in a variety of electric devices. In order to make the features and advantages of the present disclosure more comprehensible, various embodiments are specially cited hereinafter, together with the accompanying drawings, to be described in detail as follows.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1 to 8 are cross-sectional schematic views illustrating the circuit board structure at different stages in the manufacturing method according to some embodiments of the present disclosure; and

FIG. 9 is cross-sectional schematic views illustrating the circuit board structure according to other embodiments of the present disclosure.

### DETAILED DESCRIPTION OF THE INVENTION

The devices of various embodiments of the present disclosure will be described in detail below. It should be understood that the following description provides many different embodiments for implementing various aspects of some embodiments of the present disclosure. The specific elements and arrangements described below are merely to clearly describe some embodiments of the present disclosure. Of course, these are only used as examples rather than limitations of the present disclosure. Furthermore, similar or corresponding reference numerals may be used in different embodiments to designate similar or corresponding elements in order to clearly describe the present disclosure. However, the use of these similar or corresponding reference numerals is only for the purpose of simply and clearly describing some embodiments of the present disclosure, and does not imply any correlation between the different embodiments or structures discussed.

In addition, it should be understood that ordinal numbers such as “first”, “second”, and the like used in the description and claims are used to modify elements and are not intended to imply and represent the element(s) have any previous ordinal numbers, and do not represent the order of a certain element and another element, or the order of the manufacturing method, and the use of these ordinal numbers is only used to clearly distinguish an element with a certain name and another element with the same name. The claims and the specification may not use the same terms, for example, a first element in the specification may be a second element in the claim.

In some embodiments of the present disclosure, terms related to bonding and connection, such as “connect”, “interconnect”, “bond”, and the like, unless otherwise defined, may refer to two structures in direct contact, or may also refer to two structures not in direct contact, that is there is another structure disposed between the two structures. Moreover, the terms related to bonding and connection may also include embodiments in which both structures are movable, or both structures are fixed. Furthermore, the terms “electrically connected” or “electrically coupled” include any direct and indirect means of electrical connection.

Herein, the terms “approximately”, “about”, and “substantially” generally mean within 10%, within 5%, within 3%, within 2%, within 1%, or within 0.5% of a given value or range. The given value is an approximate value, that is, “approximately”, “about”, and “substantially” may still be implied without the specific description of “approximately”, “about”, and “substantially”. The phrase “a range between a first value and a second value” means that the range includes the first value, the second value, and other values in between. Furthermore, any two values or directions used for comparison may have certain tolerance. If the first value is equal to the second value, it implies that there may be a tolerance within about 10%, within 5%, within 3%, within 2%, within 1%, or within 0.5% between the first value and the second value. If the first direction is perpendicular to the second direction, the angle between the first direction and the second direction may be between 80 degrees and 100 degrees. If the first direction is parallel to the second direction, the angle between the first direction and the second direction may be between 0 degrees and 10 degrees.

It should be understood that, in the following embodiments, features in several different embodiments may be replaced, recombined, and bonded to complete other embodiments without departing from the spirit of the present disclosure. The features of the various embodiments may be used in any combination as long as they do not violate the spirit of the present disclosure or conflict with each other.

Unless otherwise defined, all terms (including technical and scientific terms) used herein have the same meaning as commonly understood by a person of ordinary skill in the art. It is understood that these terms, such as those defined in commonly used dictionaries, should be interpreted as having meanings consistent with the relevant art and the background or context of the present disclosure, and should not be interpreted in an idealized or overly formal manner, unless otherwise defined in the embodiments of the present disclosure.

In circuit board structures, multiple circuit patterns can be disposed on a substrate to achieve specific functions. The overlap area between the circuit patterns and the substrate (e.g., viewed in a projected manner) can be defined as circuit density or residual copper ratio (detailed calculations are described below). Different circuit patterns may have differences in circuit density (or residual copper ratio). As the number and complexity of circuit patterns increase, the differences in circuit density (or residual copper ratio) become more significant. This makes it difficult for the dielectric material disposed on the circuit pattern to form a blanket-covered structure. For example, in areas with high circuit density, the dielectric material is difficult to fill the gaps between lines by flow. On the other hand, in areas with low circuit density, the dielectric material may create a collapsed surface due to excessive filling of the gaps between lines. As a result, poor dielectric thickness uniformity may occur, which in turn affects subsequent processes or device stability.

To address at least some of the aforementioned problems, the present disclosure provides a cover layer disposed on circuit patterns having a lower circuit density, so as to reduce structural differences between regions with high circuit density and regions with low circuit density. Specifically, the cover layer can completely cover the circuit patterns having a lower circuit density, so as to serve as a support such that a dielectric layer formed in subsequent processes can be disposed in a planar manner. In other words, the present disclosure provides a circuit board structure with excellent dielectric thickness uniformity and a manufacturing method of the same.

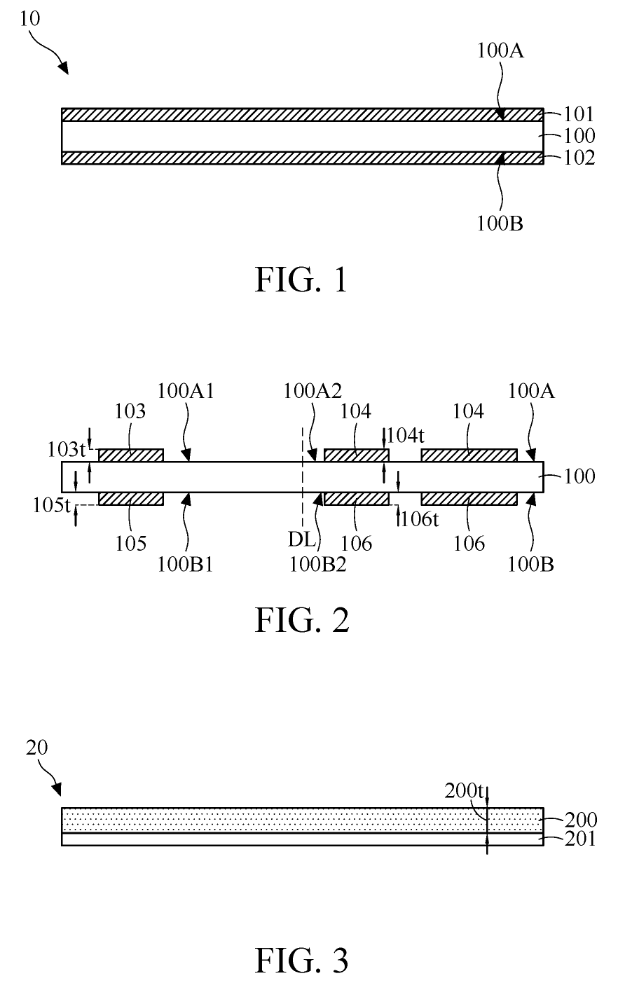

FIGS. 1 to 8 are schematic cross-sectional views illustrating the circuit board structure at different stages in the manufacturing process according to some embodiments of the present disclosure. It should be noted that, for simplicity and ease of understanding, the figures in the present disclosure may exaggerate the dimensions of components and the proportions between them. Furthermore, the figures in the present disclosure may omit some components in the circuit board structure, but a person having ordinary skills in the art will understand that the circuit board structure may also include other common components, such as active components, passive components, pads, and redistribution layers (RDLs).

As shown in FIG. 1, the base substrate 10 is provided. The base substrate 10 may include the substrate 100, the conductor layer 101, and the conductor layer 102, wherein the conductor layer 101 and the conductor layer 102 are respectively disposed on the upper surface 100A and the lower surface 100B of the substrate 100.

In some embodiments, the substrate 100 may include polymeric materials, fibrous materials, prepreg, other suitable materials, or a combination thereof, but the present disclosure is not limited thereto. For example, polymeric materials may include epoxy resin, polyimide (PI), polypropylene (PP), other suitable polymeric materials, or a combination thereof, but the present disclosure is not limited thereto. For example, fibrous materials may include carbon fiber, glass fiber, other suitable fibrous materials, or a combination thereof, but the present disclosure is not limited thereto. In some embodiments, the conductor layer 101 and/or the conductor layer 102 may include aluminum (Al), copper (Cu), an alloy thereof, or a compound thereof, but the present disclosure is not limited thereto. For example, copper alloys or compounds may include brass, phosphor bronze, beryllium bronze, or oxygen-free copper, but the present disclosure is not limited thereto. In some embodiments, the base substrate 10 is a copper foil substrate.

As shown in FIG. 2, following the steps described above, the conductor layer 101 is patterned to form a plurality of circuit patterns on the upper surface 100A of the substrate 100. For example, the conductor layer 101 may be patterned as the first circuit pattern 103 and the second circuit pattern 104. In some embodiments, the plurality of circuit patterns located on the same side of the base substrate 10 may be separated from each other to perform different functions. For example, the first circuit pattern 103 and the second circuit pattern 104 on the upper surface 100A of the substrate 100 may be used as an audio signal transmission line and an image signal transmission line, respectively, but the present disclosure is not limited thereto. Alternatively, these circuit patterns may also be different regions of a single circuit and together perform a specific function. For example, the first circuit pattern 103 and the second circuit pattern 104 on the upper surface 100A of the substrate 100 may be used together as a power transmission line, but the present disclosure is not limited thereto.

In some embodiments, the first circuit pattern 103 has the first circuit thickness 103t, the second circuit pattern 104 has the second circuit thickness 104t, and the first circuit thickness 103t is substantially the same as the second circuit thickness 104t. However, the present disclosure is not limited thereto. In other embodiments, the first circuit thickness 103t may be different from the second circuit thickness 104t.

Following the steps described above, the conductor layer 102 is patterned to form a plurality of circuit patterns on the lower surface 100B of the substrate 100. For example, the conductor layer 102 may be patterned as the third circuit pattern 105 and the fourth circuit pattern 106. Similarly, these circuit patterns may each perform different specific functions, or together perform a certain specific function.

In some embodiments, the third circuit pattern 105 has the third circuit thickness 105t, the fourth circuit pattern 106 has the fourth circuit thickness 106t, and the third circuit thickness 105t is substantially the same as the fourth circuit thickness 106t. However, the present disclosure is not limited thereto. In other embodiments, the third circuit thickness 105t may be different from the fourth circuit thickness 106t.

In the present disclosure, when viewed from above (i.e., along the normal direction of substrate 100), the ratio of the projected area of the circuit pattern (i.e., the area of the circuit pattern itself overlapping the substrate) to the area of a selected region is called the circuit density or residual copper ratio. For example, when the projected area of the circuit pattern (i.e., the total area of the conductor viewed from above) is x, and the area of the selected region is y (where x≤y), the circuit density or residual copper ratio is defined as x/y (which may also be expressed as a percentage). The circuit density (or residual copper ratio) of this selected region will be used in subsequent processes to determine whether the region is provided with a cover layer. In some embodiments, the smallest area of a rectangle, circle, or other suitable shape that may cover the entire circuit pattern may be used as the selected region to determine the circuit density (or residual copper ratio) under this condition. However, the present disclosure is not limited thereto. In other embodiments, any suitable region may be arbitrarily selected as the selected region to determine the circuit density (or residual copper ratio) under this condition. In some embodiments, when there is no circuit pattern in the selected area, the circuit density (or residual copper ratio) of this area may be defined to be substantially 0%. Conversely, when the selected area is completely covered by a circuit pattern, the circuit density (or residual copper ratio) of this area may be defined to be substantially 100%.

As described above, the first circuit pattern 103 and the second circuit pattern 104 may have different circuit densities. For example, the first circuit pattern 103 may have a first circuit density (i.e., the ratio of the total top view area of the first circuit pattern 103 to the area 100A1), and the second circuit pattern 104 may have a second circuit density (i.e., the ratio of the total top view area of the second circuit pattern 104 to the area 100A2), wherein the second circuit density is greater than the first circuit density. In other words, the second circuit pattern 104 is denser than the first circuit pattern 103 per unit area. For ease of understanding, FIG. 2 divides the substrate 100 into an upper left half (with the area 100A1) and an upper right half (with the area 100A2) of the same size by a dashed line DL, such that the area 100A1 is substantially the same as the area 100A2. However, as mentioned above, in other embodiments, the position of the dashed line DL may be arbitrarily chosen as needed, or the areas 100A1 and 100A2 may be arbitrarily defined to be different from each other.

Similarly, the third circuit pattern 105 and the fourth circuit pattern 106 may have different circuit densities. For example, the third circuit pattern 105 may have a third circuit density (i.e., the ratio of the total top view area of the third circuit pattern 105 to area 100B1), and the fourth circuit pattern 106 may have a fourth circuit density (i.e., the ratio of the total top view area of the fourth circuit pattern 106 to area 100B2), wherein the fourth circuit density is greater than the third circuit density. In other words, the fourth circuit pattern 106 is denser than the third circuit pattern 105 per unit area. For ease of understanding, FIG. 2 divides the substrate 100 into a lower left half (with the area 100B1) and a lower right half (with the area 100B2) of the same size by a dashed line DL, such that area 100B1 is substantially the same as area 100B2. However, as mentioned above, in other embodiments, the position of the dashed line DL may be arbitrarily chosen as needed, or the areas 100B1 and 100B2 may be arbitrarily defined to be different from each other.

In some embodiments, the conductor layer 101 and/or the conductor layer 102 may be patterned by a combination of photolithography and etching processes. In some embodiments, the photolithography process may include photoresist application (e.g., spin-on coating, lamination), soft baking, mask alignment, exposure, post-exposure baking, photoresist developing, rinsing, drying (e.g., spin-drying and/or hard baking), other suitable photolithography techniques, and/or a combination thereof, but the present disclosure is not limited thereto. In some embodiments, the etching process may include dry etching, wet etching, other suitable etching, or a combination thereof, but the present disclosure is not limited thereto.

As shown in FIG. 3, following the steps described above, the dielectric film 20 is provided, which includes the cover film 200 and the release film 201. Specifically, the cover film 200 is configured to cover circuit patterns in subsequent processes to effectively reduce circuit density mismatches between multiple circuit patterns. To enable the cover film 200 to effectively cover circuit patterns or fill gaps between circuit patterns, a material with high fluidity under specific conditions may be selected. For example, the cover film 200 may include a thermosetting or photocurable material that softens or melts upon application to cover the circuit patterns. In addition, the cover film 200 may also have physical or chemical properties that match the circuit patterns. For example, to meet electrical requirements, the cover film 200 may be selected from materials with a low dielectric constant. Alternatively, to meet flame retardancy requirements, the cover film 200 may be selected from materials with a high flame-retardant property. In other words, a person having ordinary skills in the art may select a suitable material as the cover film 200 based on requirements, while ensuring easy coverage of the circuit patterns.

In some embodiments, the thickness 200t of the cover film 200 is greater than the thickness of the circuit pattern (e.g., the first circuit thickness 103t or the second circuit thickness 104t). For example, the thickness 200t of the cover film 200 may be 1.1 to 5 times the thickness of the circuit pattern (e.g., the first circuit thickness 103t or the second circuit thickness 104t), such as 1.5 times, 2 times, 3 times, 4 times, 5 times, or any value or range between the above values, but the present disclosure is not limited thereto. When the thickness 200t is insufficient (e.g., similar to or less than the thickness of the circuit pattern), a portion of the circuit pattern may be exposed from the cover layer (formed from the cover film 200). Conversely, when the thickness 200t is too high (e.g., much greater than the thickness of the circuit pattern), the cover film 200 may excessively affect the dielectric constant of the entire device, making it difficult to meet design requirements.

In some embodiments, the cover film 200 includes polymeric materials such as polyphenylene oxide (PPO), polyphenylene ether (PPE), polytetrafluoroethylene (PTFE), bismaleimide triazine (BT), Ajinomoto build-up film (ABF), other suitable materials, or a combination thereof, but the present disclosure is not limited thereto. In some embodiments, the cover film 200 may also optionally include fibrous materials such as carbon fiber, glass fiber, quartz fiber, other suitable fibrous materials, or a combination thereof to improve the mechanical strength, dimensional stability, or heat resistance of the cover film 200, but the present disclosure is not limited thereto.

On the other hand, the release film 201 is configured to provide sufficient mechanical support for the cover film 200 before it is handled, bonded, or formed on a substrate. In some embodiments, the release film 201 may include polyethylene terephthalate (PET), polyimide (PI), polyolefin materials, other suitable polymer materials, or a combination thereof, but the present disclosure is not limited thereto.

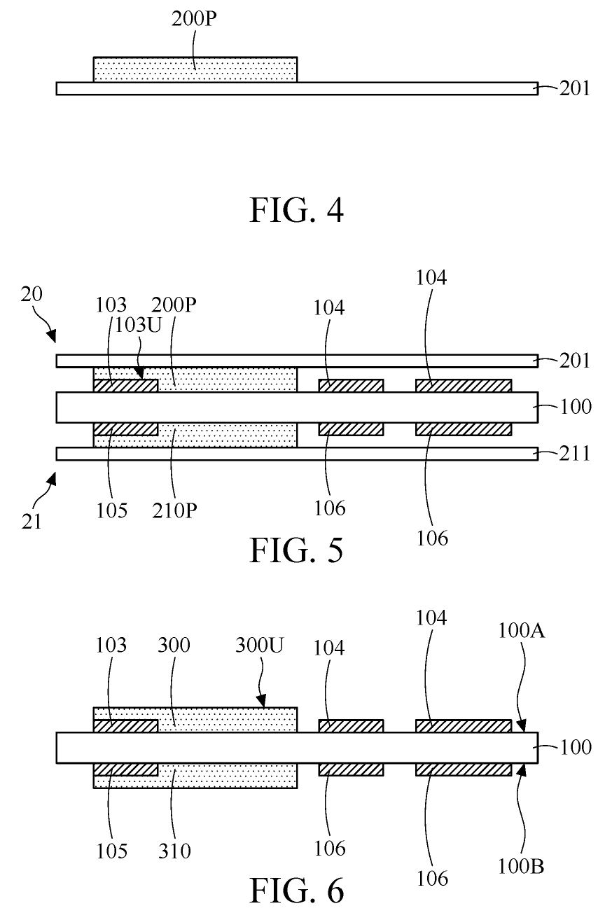

As shown in FIG. 4, following the steps described above, a portion of the cover film 200 is removed, leaving another portion of the cover film 200 (e.g., the cover film 200P). The remaining cover film 200P will be attached to the circuit pattern to form a cover layer for supporting the dielectric layer (e.g., the first cover layer or the second cover layer hereinafter). In other words, the present disclosure selectively provides a cover layer at specific locations on the substrate 100, rather than providing a cover layer between the entire substrate 100 and the dielectric layer.

In some embodiments, the location of the remaining cover film 200P may be determined based on the circuit density. For example, when the circuit density of a selected area is less than or equal to 50%, the cover film 200 corresponding to this area may be retained to form a cover layer on this area in subsequent processes. Conversely, when the circuit density of another selected area is greater than 50%, the cover film 200 corresponding to this area may be removed to prevent the formation of a cover layer on this area in subsequent processes. In other words, a cover layer may be formed on areas with lower circuit density, but not on areas with higher circuit density. Of course, the above values are merely examples, and the present disclosure is not limited thereto. A person having ordinary skills in the art may determine the threshold for the circuit density corresponding to the removal of the cover film 200 based on design requirements. For example, “circuit density less than or equal to 80%” may be defined as the threshold, and the cover film 200 may be left in the corresponding local area.

In some embodiments, the top view shape of the cover film 200P may be triangular, circular, elliptical, rectangular, polygonal, or other suitable shapes. For example, the top view shape of the cover film 200P may be determined based on the top view shape of the circuit pattern. In some embodiments, the top view area of the cover film 200P is larger than the top view area of the circuit pattern to achieve a good covering effect. In some embodiments, the sidewall shape of the cover film 200P may be vertical, protruding, or recessed.

As shown in FIG. 4, the cover film 200P may be left according to the first circuit density of the first circuit pattern 103, and the corresponding portion of the cover film 200 may be removed according to the second circuit density of the second circuit pattern 104. In some embodiments, the first circuit density is less than or equal to 80%, while the second circuit density is greater than 80%.

In some embodiments, another dielectric film (e.g., the dielectric film 21 of FIG. 5) may be provided, and a portion of the cover portion may be removed in the manner described above, leaving another portion of the cover portion (e.g., the cover portion 210P of FIG. 5). For example, a portion of the cover portion (e.g., the cover portion 210P of FIG. 5) may be left according to the third circuit density of the third circuit pattern 105, and another portion of the cover portion may be removed according to the fourth circuit density of the fourth circuit pattern 106. In some embodiments, the third circuit density is less than or equal to 80%, while the fourth circuit density is greater than 80%.

As shown in FIG. 5, following the steps described above, the dielectric film 20 is disposed on the substrate 100. Specifically, the cover film 200P is disposed on the first circuit pattern 103 and covers the first circuit pattern 103. Since there is no corresponding cover film 200 on the second circuit pattern 104, the second circuit pattern 104 is exposed to the air. However, the present disclosure is not limited to this. In other embodiments, a portion of the cover film 200 may be retained on the second circuit pattern 104 to form a second cover layer (e.g., the second cover layer 301 in FIG. 9).

In some embodiments, the cover film 200P may completely cover the first circuit pattern 103 so that neither the upper surface 103U nor the side surface 103S of the first circuit pattern 103 is exposed, but the present disclosure is not limited thereto. In other embodiments, the cover film 200P may partially cover the first circuit pattern 103 so that the upper surface 103U of the first circuit pattern 103 is not exposed, but the side surface 103S is exposed.

Following the steps described above, the dielectric film 21 is disposed on the substrate 100. Specifically, the cover portion 210P is disposed on and covers the third circuit pattern 105. Since there is no corresponding cover film on the fourth circuit pattern 106, the fourth circuit pattern 106 is exposed to air. Similarly, the cover portion 210P may completely or partially cover the third circuit pattern 105. These configurations may be determined according to design requirements (e.g., electrical requirements).

In some embodiments, the dielectric film 20 and/or the dielectric film 21 may be disposed on substrate 100 by means of a vacuum laminator or similar equipment, but the present disclosure is not limited thereto.

As shown in FIG. 6, following the steps described above, the cover film 200P may be softened or melted by applying heat or pressure, and the cover film 200P may be cooled to form the first cover layer 300 with a blanket structure on the substrate 100.

In some embodiments, to improve the interface adhesion between the first cover layer 300 and the substrate 100 and the circuit pattern, the surface of the circuit pattern and the exposed surface of the substrate 100 may be subjected to surface modification treatment before the cover film 200P is applied. Surface modification treatment may include black oxide treatment, brown oxide treatment, micro-etching, plasma treatment, or coating with a coupling agent (e.g., a silane coupling agent).

Specifically, the aforementioned surface treatment may increase the roughness of the circuit pattern surface, thereby enhancing its bonding strength with the first cover layer 300 through mechanical interlocking. Simultaneously, if the first cover layer 300 contains a resin component (such as epoxy resin), the coupling agent may form chemical bonds between the inorganic conductor interface and the organic polymer interface, thereby reducing the risk of delamination during thermal expansion.

Following the steps described above, the release film 201 is removed to expose the upper surface 300U of the first cover layer 300. In some embodiments, the release film 201 may be removed by direct peeling/demolding, dicing-assisted removal, thermal softening, thermal decomposition/burnout, solvent dissolution, chemical etching, laser debonding/laser release, UV release, other suitable methods, or a combination thereof, but the present disclosure is not limited thereto.

In some embodiments, after removing the release film 201, the upper surface 300U of the first cover layer 300 may be roughened or activated as needed to facilitate the formation of a tight bonding interface between the subsequently applied dielectric layer (not shown) and the first cover layer 300 and the circuit pattern. By controlling the coefficient of thermal expansion (CTE) matching between the first cover layer 300 and the circuit pattern (e.g., ensuring that the CTE difference between the two is less than or equal to 20 ppm/°C), the reliability of the circuit board structure in thermal cycling tests may be further ensured.

Similar to the definition of circuit density above, in the present disclosure, when viewed from above (i.e., along the normal direction of the substrate 100), the ratio of the projected area of the circuit pattern and the first cover layer 300 (e.g., the total area of the first cover layer 300 overlapping the substrate) to the area of a selected region is called the coverage density. In some embodiments, the first cover layer 300 may be selectively disposed on the upper surface 100A of the substrate 100 to make the coverage density of various local regions on the substrate 100 consistent. In other words, when a region has a high circuit density, a cover layer may be optionally not disposed in this region, so that the coverage density of this region is substantially the circuit density. On the other hand, when another region has a lower circuit density, a cover layer may be optionally disposed in this region until the coverage density of this region increases. In this way, the coverage density of various local regions of the substrate 100 may be adjusted to be similar or even the same, thereby improving the planarization of the dielectric layer in subsequent processes.

Following the steps described above, the cover portion 210P of the dielectric film 21 may be softened or melted by applying heat or pressure, and the cover portion 210P may be cooled to form the first cover layer 310 with a blanket structure on the substrate 100. In some embodiments, the third circuit pattern 105, the first cover layer 310, or the lower surface 100B of the substrate 100 may be surface-treated with reference to the above process, thus the descriptions thereof are omitted.

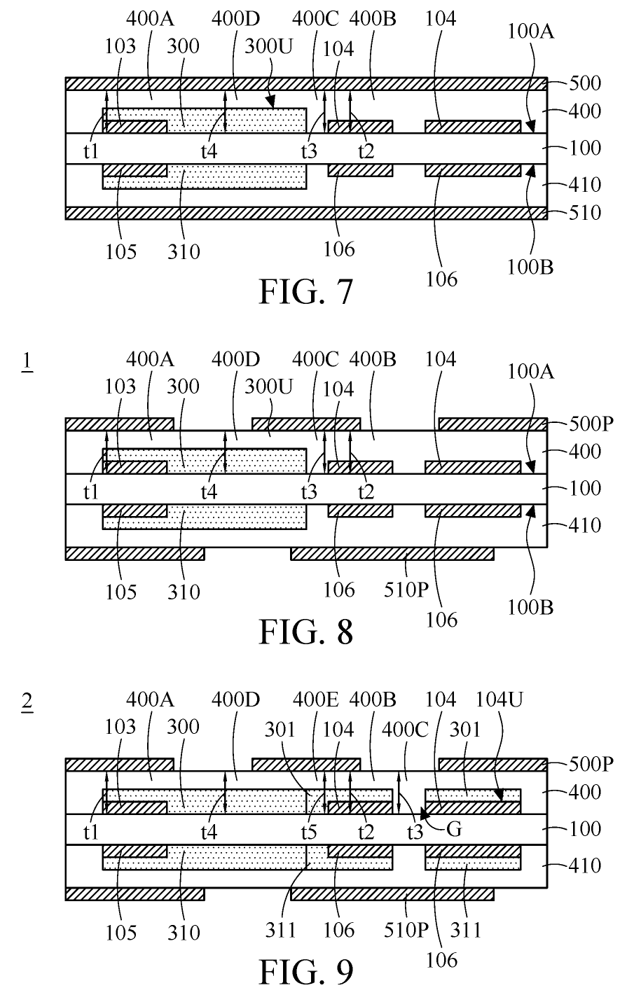

As shown in FIG. 7, following the steps described above, a lamination process is performed at a lamination temperature to form the dielectric layer 400 on the first cover layer 300 and the second circuit pattern 104. In some embodiments, the dielectric material may be softened or melted by applying heat or pressure to form a dielectric material layer with a blanket structure on the substrate 100, and then the dielectric material layer is cured to form the dielectric layer 400. In some cases, to avoid the first cover layer 300 from softening or melting again, the glass transition temperature or melting point of the first cover layer 300 needs to be greater than the lamination temperature. In other words, the material of the first cover layer 300 may be different from the material of the dielectric layer 400. Alternatively, both the first cover layer 300 and the dielectric layer 400 may include the same thermosetting or photocurable material, and the above-mentioned problem may be avoided by the characteristic that it does not soften after curing. In this case, the material of the first cover layer 300 may be the same as the material of the dielectric layer 400.

In some embodiments, the dielectric layer 400 may be divided into multiple portions according to its location. For example, the dielectric layer 400 may include the first portion 400A and the second portion 400B. The first portion 400A covers the upper surface 300U of the first cover layer 300 and the first circuit pattern 103 located thereunder, and the first portion 400A, the first cover layer 300, and the first circuit pattern 103 together have the first thickness t1. The second portion 400B covers the second circuit pattern 104, and the second portion 400B and the second circuit pattern 104 together have the second thickness t2. In some embodiments, │(t1-t2)│≤30µm. For example, the difference between the first thickness t1 and the second thickness t2 may be 30µm, 25µm, 20µm, 15µm, 10µm, 5µm, 0µm, or any value or range between the above values. In some embodiments, │(t1-t2)│/(t1+t2) may be defined as the degree of thickness variation of the circuit board structure between the first portion 400A and the second portion 400B, and │(t1-t2)│/(t1+t2)≤40%. For example, the degree of thickness variation may be 40%, 35%, 30%, 25%, 20%, 15%, 10%, 5%, 0%, or any value or range between the above values. As expressed by the formula, the smaller the difference between the first thickness t1 and the second thickness t2, the higher the flatness of the high circuit density region and the low circuit density region.

In some embodiments, the dielectric layer 400 further includes the third portion 400C. The third portion 400C covers and is in contact with the upper surface 100A of the substrate 100, wherein the third portion 400C has the third thickness t3. Specifically, there is no circuit pattern between the third portion 400C and the substrate 100, that is, the third thickness t3 is the thickness of the dielectric layer 400 itself. In some embodiments, │(t1-t3)│≤30µm. For example, the difference between the first thickness t1 and the third thickness t3 may be 30µm, 25µm, 20µm, 15µm, 10µm, 5µm, 0µm, or any value or range between the above values. In some embodiments, │(t1-t3)│/(t1+t3) may be defined as the degree of thickness variation between the first portion 400A and the third portion 400C of the substrate 100, and │(t1-t3)│/(t1+t3)≤40%. For example, the degree of thickness variation may be 40%, 35%, 30%, 25%, 20%, 15%, 10%, 5%, 0%, or any value or range between the above values. As expressed by the formula, the smaller the difference between the first thickness t1 and the third thickness t3, the higher the flatness of the wiring area and the non-wiring area.

In some embodiments, the dielectric layer 400 further includes the fourth portion 400D. The fourth portion 400D covers the upper surface 300U of the first cover layer 300 and does not have the first circuit pattern 103 underneath it. In other words, the fourth portion 400D does not overlap with the circuit pattern. The fourth portion 400D and the first cover layer 300 together have the fourth thickness t4. In some embodiments, │(t1-t4) │≤30µm. For example, the difference between the first thickness t1 and the fourth thickness t4 may be 30µm, 25µm, 20µm, 15µm, 10µm, 5µm, 0µm, or any value or range between the above values. In some embodiments, │(t1-t4)│/(t1+t4) may be defined as the degree of thickness variation of the circuit board structure between the first portion 400A and the fourth portion 400D, and │(t1-t4)│/(t1+t4)≤40 %. For example, the degree of thickness variation may be 40%, 35%, 30%, 25%, 20%, 15%, 10%, 5%, 0%, or any value or range between the above values. As expressed by the formula, the smaller the difference between the first thickness t1 and the fourth thickness t4, the higher the flatness of the covered wiring area and the covered non-wiring area.

As shown in FIG. 7, following the steps described above, another lamination process is performed at the lamination temperature to form the dielectric layer 410 on the first cover layer 310 and the fourth circuit pattern 106. In some embodiments, the dielectric material may be softened or melted by applying heat or pressure to form a dielectric material layer with a blanket structure on the substrate 100, and then the dielectric material layer is cured to form the dielectric layer 410. In some cases, to avoid the first cover layer 310 from softening or melting again, the glass transition temperature or melting point of the first cover layer 310 needs to be greater than the lamination temperature. In other words, the material of the first cover layer 310 may be different from the material of the dielectric layer 410. Alternatively, both the first cover layer 310 and the dielectric layer 410 may include the same thermosetting or photocurable material, and the above-mentioned problem may be avoided by the characteristic that it does not soften after curing. In this case, the material of the first cover layer 310 may be the same as the material of the dielectric layer 410.

It should be noted that the thickness difference or degree of thickness variation between the substrate 100 and the first cover layer 310, the third circuit pattern 105, and the fourth circuit pattern 106 may be referred to and applied using the formulas and values described above, and the descriptions thereof are omitted. In the present disclosure, by providing cover layers (e.g., the first cover layer 300 and the first cover layer 310), the dielectric thickness difference at various locations on the substrate 100 may be significantly reduced. These various locations include, for example, wiring areas with cover layers, non-wiring areas with cover layers, wiring areas without cover layers, and non-wiring areas without cover layers.

Through the above-described process, a circuit board structure with a flat upper surface (outermost surface) may be obtained. In some embodiments, lamination processes may be performed on the circuit board structure to form a more complex and multi-layered circuit board structure. For example, following the steps described above, the conductor layer 500 may be formed on the dielectric layer 400, and the conductor layer 510 may be formed on the dielectric layer 410. In some embodiments, the conductor layer 500 and/or the conductor layer 510 may include aluminum (Al), copper (Cu), an alloy thereof, or a compound thereof, but the present disclosure is not limited thereto. As shown in FIG. 8, following the steps described above, the conductor layer 500 and/or the conductor layer 510 may be patterned to form the circuit pattern 500P and the circuit pattern 510P. For example, the conductor layer 500 and/or the conductor layer 510 may be patterned by a combination of lithography and etching processes to obtain the circuit board structure 1.

Although the cover layers described above (i.e., the first cover layer 300 and the first cover layer 310) are only disposed on circuit patterns having a lower circuit density (e.g., less than or equal to 80%) (i.e., the first circuit pattern 103 and the third circuit pattern 105), the present disclosure is not limited thereto. In other embodiments, the cover layers may further partially cover circuit patterns having a higher circuit density (e.g., greater than 80%) (i.e., the second circuit pattern 104 and the fourth circuit pattern 106). More specifically, the cover layers may partially cover the circuit patterns having a higher circuit density, while exposing a portion of the circuit patterns or gaps between adjacent lines.

FIG. 9 is a cross-sectional schematic diagram of the circuit board structure according to some other embodiments of the present disclosure. As shown in FIG. 9, the circuit board structure 2 further includes a second cover layer 301. The second cover layer 301 is disposed on the substrate 100 and partially covers the second circuit pattern 104. As mentioned above, due to the high circuit density of the second circuit pattern 104, the second cover layer 301 may not easily fill the gaps G between adjacent lines in the second circuit pattern 104. Therefore, the second cover layer 301 may substantially cover the peripheral area of the second circuit pattern 104 and expose the central area of the second circuit pattern 104. Alternatively, it may cover all the upper surfaces 104U of the second circuit pattern 104, but not fill all the gaps G in the second circuit pattern 104. In other words, the second cover layer 301 may completely overlap with the second circuit pattern 104.

In some embodiments, the dielectric layer 400 includes the first portion 400A, the second portion 400B, the third portion 400C, and the fourth portion 400D. The first portion 400A covers the upper surface 300U of the first cover layer 300 and the first circuit pattern 103 located thereunder. The first portion 400A, the first cover layer 300, and the first circuit pattern 103 together have the first thickness t1. The second portion 400B covers and is in contact with the upper surface of the second cover layer 301 and the second circuit pattern 104 located thereunder. The second portion 400B, the second cover layer 301, and the second circuit pattern 104 together have the second thickness t2. In some embodiments, │(t1-t2)│≤30µm. For example, the difference between the first thickness t1 and the second thickness t2 may be 30µm, 25µm, 20µm, 15µm, 10µm, 5µm, 0µm, or any value or range between the above values. In some embodiments, │(t1-t2)│/(t1+t2) may be defined as the degree of thickness variation of the circuit board structure between the first portion 400A and the second portion 400B, and │(t1-t2)│/(t1+t2)≤40%. For example, the degree of thickness variation may be 40%, 35%, 30%, 25%, 20%, 15%, 10%, 5%, 0%, or any value or range between the above values.

The third portion 400C covers and is in contact with the upper surface 100A of the substrate 100, wherein the third portion 400C has the third thickness t3. Specifically, the third portion 400C is the part of the dielectric layer 400 that fills the gap G between adjacent lines of the second circuit pattern 104, so there is no circuit pattern between the third portion 400C and the substrate 100. In some embodiments, │(t1-t3)│≤30µm. For example, the difference between the first thickness t1 and the third thickness t3 may be 30µm, 25µm, 20µm, 15µm, 10µm, 5µm, 0µm, or any value or range between the above values. In some embodiments, │(t1-t3)│/(t1+t3) may be defined as the degree of thickness variation between the first portion 400A and the third portion 400C of the substrate 100, and │(t1-t3)│/(t1+t3)≤40%. For example, the degree of thickness variation may be 40%, 35%, 30%, 25%, 20%, 15%, 10%, 5%, 0%, or any value or range between the above values.

The fourth portion 400D covers the upper surface 300U of the first cover layer 300 and does not have the first circuit pattern 103 underneath it. In other words, the fourth portion 400D does not overlap with the circuit pattern. The fourth portion 400D and the first cover layer 300 together have the fourth thickness t4. In some embodiments, │(t1-t4) │≤30µm. For example, the difference between the first thickness t1 and the fourth thickness t4 may be 30µm, 25µm, 20µm, 15µm, 10µm, 5µm, 0µm, or any value or range between the above values. In some embodiments, │(t1-t4)│/(t1+t4) may be defined as the degree of thickness variation of the circuit board structure between the first portion 400A and the fourth portion 400D, and │(t1-t4) │/(t1+t4)≤40 %. For example, the degree of thickness variation may be 40%, 35%, 30%, 25%, 20%, 15%, 10%, 5%, 0%, or any value or range between the above values.

The fifth portion 400E covers the upper surface of the second cover layer 301 and does not have the second circuit pattern 104 underneath it. The fifth portion 400E and the second cover layer 301 together have the fifth thickness t5. In some embodiments, │(t1-t5) │≤30µm. For example, the difference between the first thickness t1 and the fifth thickness t5 may be 30µm, 25µm, 20µm, 15µm, 10µm, 5µm, 0µm, or any value or range between the above values. In some embodiments, │(t1-t5)│/(t1+t5) may be defined as the degree of thickness variation of the circuit board structure between the first portion 400A and the fifth portion 400E, and │(t1-t5)│/(t1+t5)≤40 %. For example, the degree of thickness variation may be 40%, 35%, 30%, 25%, 20%, 15%, 10%, 5%, 0%, or any value or range between the above values.

In some embodiments, the first cover layer 300 and the second cover layer 301 (or the first cover layer 310 and the second cover layer 311) may be simultaneously formed using the dielectric film 20 (or the dielectric film 21) in the steps of FIGS. 3 to 5. That is, the first cover layer 300 and the second cover layer 301 may be formed from different portions of the cover film 200 of the dielectric film 20 (correspondingly, the first cover layer 310 and the second cover layer 311 may be formed from different portions of the cover portion 210 of the dielectric film 21). In this way, the first cover layer 300 and the second cover layer 301 may be formed on the first circuit pattern 103 and the second circuit pattern 104 respectively in the same process. However, the present disclosure is not limited to this. In other embodiments, the first cover layer 300 and the second cover layer 301 may also be formed in batches using different dielectric films according to design requirements. Therefore, the various parameters (e.g., thickness, material) of the first cover layer 300 and the second cover layer 301 (or the first cover layer 310 and the second cover layer 311) may be the same or different.

In summary, the present disclosure reduces the structural difference between high and low circuit densities by providing a cover layer on a circuit pattern with low circuit density. Specifically, the cover layer may completely cover the circuit pattern with low circuit density, acting as a support to allow the dielectric layer in subsequent processes to be disposed flatly. In other words, the present disclosure provides a circuit board structure with excellent dielectric thickness uniformity and a manufacturing method of the same.

The foregoing outlines features of several embodiments of the present disclosure, so that a person of ordinary skill in the art may better understand the aspects of the present disclosure. A person of ordinary skill in the art should appreciate that, the present disclosure may be readily used as a basis for designing or modifying other processes and structures for carrying out the same purposes and/or achieving the same advantages of the embodiments introduced herein. A person of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A circuit board structure, comprising:
a substrate;
a first circuit pattern disposed on the substrate, wherein the first circuit pattern has a first circuit density;
a second circuit pattern disposed on the substrate, wherein the second circuit pattern has a second circuit density, and the second circuit density is greater than the first circuit density;
a first cover layer disposed on the substrate and covering the first circuit pattern; and
a dielectric layer, comprising:
a first portion covering and in contact with an upper surface of the first cover layer; and
a second portion covering the second circuit pattern.

2. The circuit board structure as claimed in claim 1, wherein the first portion, the first cover layer, and the first circuit pattern together have a first thickness t1, and the second portion and the second circuit pattern together have a second thickness t2, wherein │(t1-t2)│≤30µm.

3. The circuit board structure as claimed in claim 1, wherein the first portion, the first cover layer, and the first circuit pattern together have a first thickness t1, and the second portion and the second circuit pattern together have a second thickness t2, wherein │(t1-t2)│/(t1+t2)≤40%.

4. The circuit board structure as claimed in claim 1, wherein the dielectric layer further comprises:
a third portion covering and in contact with an upper surface of the substrate.

5. The circuit board structure as claimed in claim 4, wherein the first portion, the first cover layer, and the first circuit pattern together have a first thickness t1, the third portion has a third thickness t3, and │(t1-t3)│≤30µm.

6. The circuit board structure as claimed in claim 4, wherein the first portion, the first cover layer, and the first circuit pattern together have a first thickness t1, the third portion has a third thickness t3, and │(t1-t3)│/(t1+t3)≦40%.

7. The circuit board structure as claimed in claim 1, further comprising:
a second cover layer disposed on the substrate and partially covering the second circuit pattern, wherein the second portion covers and is in contact with an upper surface of the second cover layer.

8. The circuit board structure as claimed in claim 7, wherein the upper surface of the first cover layer and the upper surface of the second cover layer are coplanar.

9. The circuit board structure as claimed in claim 7, wherein the first portion, the first cover layer, and the first circuit pattern together have a first thickness t1, and the second portion, the second cover layer, and the second circuit pattern together have a second thickness t2, wherein │(t1-t2)│≤30µm.

10. The circuit board structure as claimed in claim 9, wherein the first portion, the first cover layer, and the first circuit pattern together have a first thickness t1, and the second portion, the second cover layer, and the second circuit pattern together have a second thickness t2, wherein │(t1-t2)│/(t1+t2)≤40%.

11. The circuit board structure as claimed in claim 1, wherein a material of the first cover layer is different from a material of the dielectric layer.

12. A manufacturing method of a circuit board structure, comprising:
forming a first circuit pattern on a substrate, wherein the first circuit pattern has a first circuit density;
forming a second circuit pattern on the substrate, wherein the second circuit pattern has a second circuit density, and the second circuit density is greater than the first circuit density;
forming a first cover layer on the first circuit pattern, wherein the first cover layer covers the first circuit pattern; and
forming a dielectric layer on the first cover layer and the second circuit pattern.

13. The manufacturing method of the circuit board structure as claimed in claim 12, wherein the dielectric layer comprises:
a first portion covering and in contact with an upper surface of the first cover layer, wherein the first portion, the first cover layer, and the first circuit pattern together have a first thickness t1; and
a second portion covering and in contact with an upper surface of the second circuit pattern, wherein the second portion and the second circuit pattern together have a second thickness t2,
wherein │(t1-t2)│≤30µm.

14. The manufacturing method of the circuit board structure as claimed in claim 13, wherein the dielectric layer further comprises:
a third portion covering and in contact with an upper surface of the substrate, wherein the third portion has a third thickness t3,
wherein │(t1-t3)│≤30µm.

15. The manufacturing method of the circuit board structure as claimed in claim 12, wherein the dielectric layer comprises:
a first portion covering and in contact with an upper surface of the first cover layer, wherein the first portion, the first cover layer, and the first circuit pattern together have a first thickness t1; and
a second portion covering and in contact with an upper surface of the second circuit pattern, wherein the second portion and the second circuit pattern together have a second thickness t2,
wherein │(t1-t2)│/(t1+t2)≤40%.

16. The manufacturing method of the circuit board structure as claimed in claim 15, wherein the dielectric layer further comprises:
a third portion covering and in contact with an upper surface of the substrate, wherein the third portion has a third thickness t3,
wherein │(t1-t3)│/(t1+t3)≤40%.

17. The manufacturing method of the circuit board structure as claimed in claim 12, wherein the first circuit density is less than or equal to 80%.

18. The manufacturing method of the circuit board structure as claimed in claim 12, further comprising:
forming a second cover layer on the second circuit pattern, wherein the second cover layer partially covers the second circuit pattern and exposes a portion of the second circuit pattern; and
forming the dielectric layer on the first cover layer, the second cover layer, and the second circuit pattern.

19. The manufacturing method of the circuit board structure as claimed in claim 18, wherein the second circuit density is greater than 80%.

20. The manufacturing method of the circuit board structure as claimed in claim 12, wherein a material of the first cover layer is different from a material of the dielectric layer.
